(19) United States
(12) Patent Application Publication
(10) Pub. No.: US 2015/0313037 A1
(43) Pub. Date: Oct. 29, 2015

(54) PLUG MODULE HOLDER

(71) Applicant: ALL BEST PRECISION TECHNOLOGY CO., LTD., Taoyuan County (TW)

(72) Inventor: HAVEN YANG, New Taipei City (TW)

(73) Assignee: ALL BEST PRECISION TECHNOLOGY CO., LTD., Taoyuan County (TW)

(21) Appl. No.: 14/261,860

(22) Filed: Apr. 25, 2014

(51) Int. Cl. H05K 7/20; H05K 7/14

(52) U.S. Cl. CPC H05K 7/2039; H05K 7/14

(57) ABSTRACT

A plug module holder includes a casing and at least one slot formed at the front of the casing. The base is disposed at the rear of the casing, and includes at least one electrical connector disposed at the front of the base. The casing includes at least one plug channel disposed inside the casing and between the slot and the electrical connector, and at least one thermal conductor is installed on a wall of the plug channel and provided for contacting and plugging into a plug device of the plug channel, so that the plug module holder is capable of dissipating the waste heat produced by the plug device through the thermal conductor and the casing to improve the heat dissipation efficiency and the data transmission rate.

### FIELD OF THE INVENTION

The present invention relates to a plug module holder, in particular to the plug module holder capable of dissipating the waste heat produced by a plug device through a thermal conductor and a casing directly and quickly to improve the heat dissipation efficiency and data transmission rate.

### BACKGROUND OF THE INVENTION

As the technology of electronic devices advances, a plug module holder is generally required for the data transmission between various different electronic devices. However, after a plug device is plugged into the plug module holder, a gap is usually formed between the plug module holder and a wall of the plug channel, so that it is difficult to dissipate the waste heat produced by the plug device, and the low heat dissipation efficiency affects the data transmission rate of the plug module holder adversely. Therefore, it is a main subject for the present invention to design and develop a plug module holder capable of dissipating the waste heat produced by a plug device through a thermal conductor and a casing directly and quickly to improve the heat dissipation efficiency and the data transmission rate.

### SUMMARY OF THE INVENTION

In view of the drawbacks of the prior art, the inventor of the present invention based on years of experience in the related industry to conduct extensive researches and experiments, and finally developed a plug module holder in accordance with the present invention to dissipate the waste heat produced by a plug device through a thermal conductor and a casing directly and quickly, so as to improve the heat dissipation efficiency and the data transmission rate.

To achieve the aforementioned and other objectives, the present invention provides a plug module holder, comprising: a casing, having at least one slot formed at the front of the casing; and at least one base, disposed at the rear of the casing, and having at least one electrical connector disposed at the front of the base, wherein the casing includes at least one plug channel formed between the slot and the electrical connector, and at least one thermal conductor is installed on a wall of the plug channel and provided for contacting and plugging a plug device of the plug channel.

In the plug module holder, the thermal conductor includes a V-shaped thermal conductive bracket facing towards the inside of the plug channel, and a free end of the V-shaped thermal conductive bracket faces towards the base.

In the plug module holder, the casing has at least one top-and-bottom spacer disposed inside the casing for separating the upper and lower plug channels.

In the plug module holder, the thermal conductor has a V-shaped thermal conductive bracket facing towards the inside of the plug channel, and a free end of the V-shaped thermal conductive bracket faces towards the base.

In the plug module holder, the top-and-bottom spacer is a U-shaped top-and-bottom partition panel, and the U-shaped top-and-bottom partition panel has an opening facing the front of the base, and the V-shaped thermal conductive bracket is disposed on a top side, a bottom side and both top and bottom sides of the U-shaped top-and-bottom partition panel.

In the plug module holder, the casing has at least one left-and-right spacer, and the left-and-right spacer is disposed in the casing for partitioning left and right plug channels.

In the plug module holder, the thermal conductor has a V-shaped thermal conductive bracket installed in the thermal conductor and facing towards the plug channel, and a free end of the V-shaped thermal conductive bracket faces towards the base.

In the plug module holder, the left-and-right spacer is a left-and-right partition panel, and the V-shaped thermal conductive bracket is disposed on a left side, a right side or both left and right sides of the left-and-right partition panel.

Therefore, the plug module holder of the present invention is capable of dissipating the waste heat produced by the plug device through the thermal conductor and the casing quickly to improve the heat dissipation efficiency and the data transmission rate.

### BRIEF DESCRIPTION OF THE DRAWINGS

FIG. 1 is a first exploded view of a preferred embodiment of the present invention;

FIG. 2 is a second exploded view of a preferred embodiment of the present invention;

FIG. 3 is a perspective view of a preferred embodiment of the present invention;

FIG. 4 is a first schematic view showing an application of a preferred embodiment of the present invention;

FIG. 5 is a second schematic view showing an application of a preferred embodiment of the present invention; and

FIG. 6 is a third schematic view showing an application of a preferred embodiment of the present invention.

### DETAILED DESCRIPTION OF THE PREFERRED EMBODIMENTS

The objects, characteristics and effects of the present invention will become apparent with the detailed description of the preferred embodiments and the illustration of related drawings as follows.

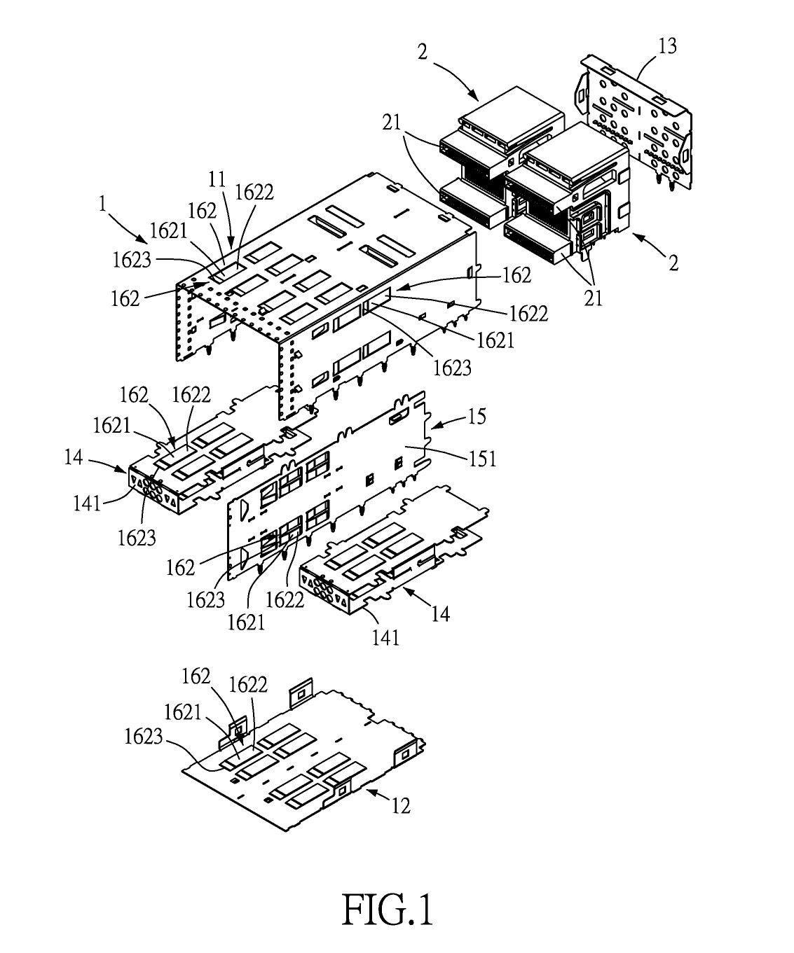

With reference to FIGS. 1 to 4 for the first and second exploded views, perspective view and schematic view of a plug module holder of a preferred embodiment of the present invention respectively, the plug module holder comprises a casing 1 and at least one base 2, wherein the casing 1 is made of metal or any other thermal conductive material, and the casing 1 includes an inverted U-shaped upper casing 11, a chassis 12 and a rear panel 13 which can be engaged with each other, and the rear panel 13 is installed at the rear side of the inverted U-shaped upper casing 11, and the chassis 12 is installed at the front on the bottom side of the inverted U-shaped upper casing 11, and an installing slot (not shown in the figure) is reserved at the rear of the bottom side of the inverted U-shaped upper casing 11. It is noteworthy that there are two bases 2 as shown in the figure, but the quantity of bases 2 may be increased or decreased according to actual requirements. Wherein, at least one slot 161 is formed at the front of the casing 1, and there are four slots 161 as shown in the figures, and the quantity of slots 161 may be increased or decreased according to actual requirements. The slot 161 is provided for passing a plug device 3 and the casing 1 is provided for covering the portion of the slot 161 with the plug device 3 plugged into the slot 161. The base 2 is mounted onto the rear of the casing 1 through the installing slot (not shown in the figure), and the bottom of the base 2 is provided for electrically connecting a circuit board (not shown in the figure), and the front of the base 2 has at least one electrical connector 21, and a light guide 22 is installed separately on both sides of the base 2. It is noteworthy that there are two electrical connectors 21 installed on both upper and lower partitions of each base 2, but the quantity of electrical connectors 21 may be increased or decreased according to actual requirements, and the electrical connector 21 is provided for electrically connecting a plug device 3, and the casing 1 includes at least one plug channel 16 formed therein and disposed between the slot 161 and the electrical connector 21. It is noteworthy that there are four plug channels 16 as shown in the figures, but the quantity of plug channels 16 may be increased or decreased according to actual requirements. The plug channel 16 is provided for accommodating a plug device 3, and the quantities of slots 161, plug channels 16 and electrical connectors 21 are equal, and a wall of the plug channel 16 has at least one thermal conductor 162, wherein the wall of the plug channel 16 refers to a combination of all walls surrounding the plug channel 16, and particularly refers to the combination of the top, bottom, left and right walls in this preferred embodiment. In the figures, the four walls (including the top, bottom, left and right walls) of the plug channel 16 have the thermal conductor 162 installed thereon, and the thermal conductor 162 may be installed on a certain wall or a portion of the wall of the plug channel 16 according to actual requirements, and the quantity of thermal conductors 162 may be increased or decreased according to actual requirements, and the thermal conductor 162 is provided for contacting an external wall of a plug device 3 plugged into the plug channel 16 for quickly absorbing and transmitting the waste heat produced by the plug device 3 to the casing 1, and then the waste heat on the casing 1 is dissipated to the atmosphere by convection.

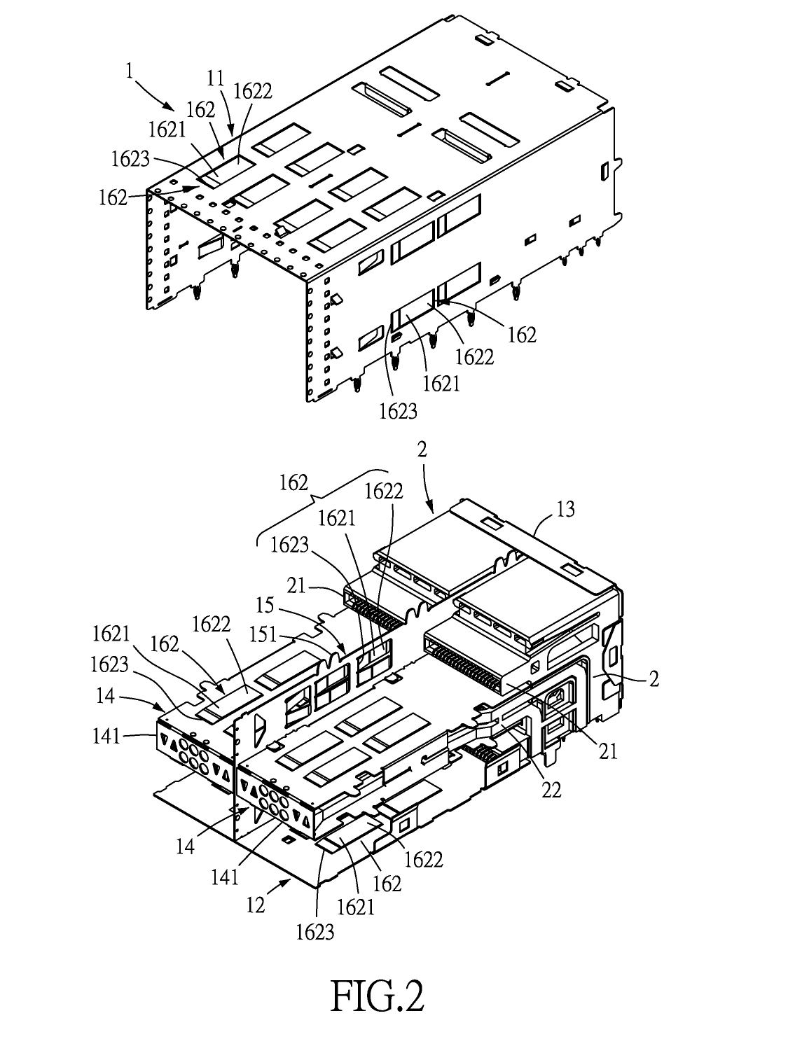

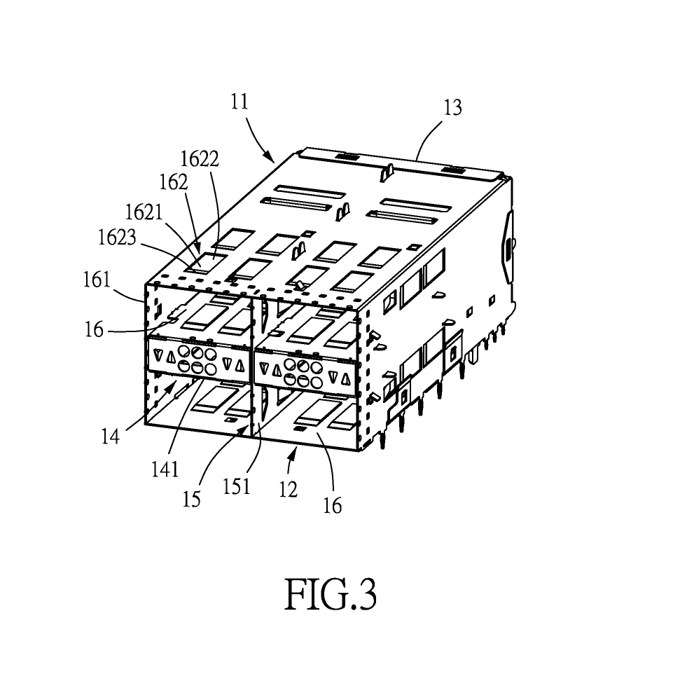

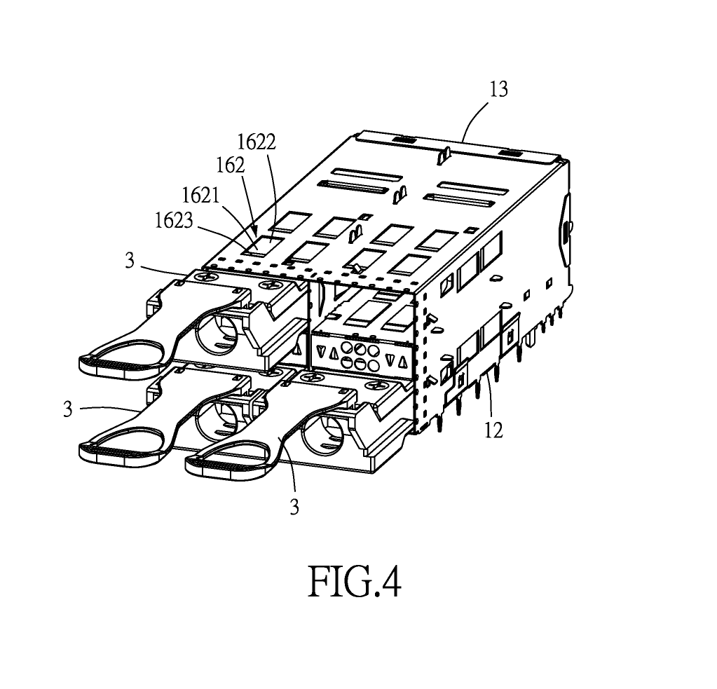

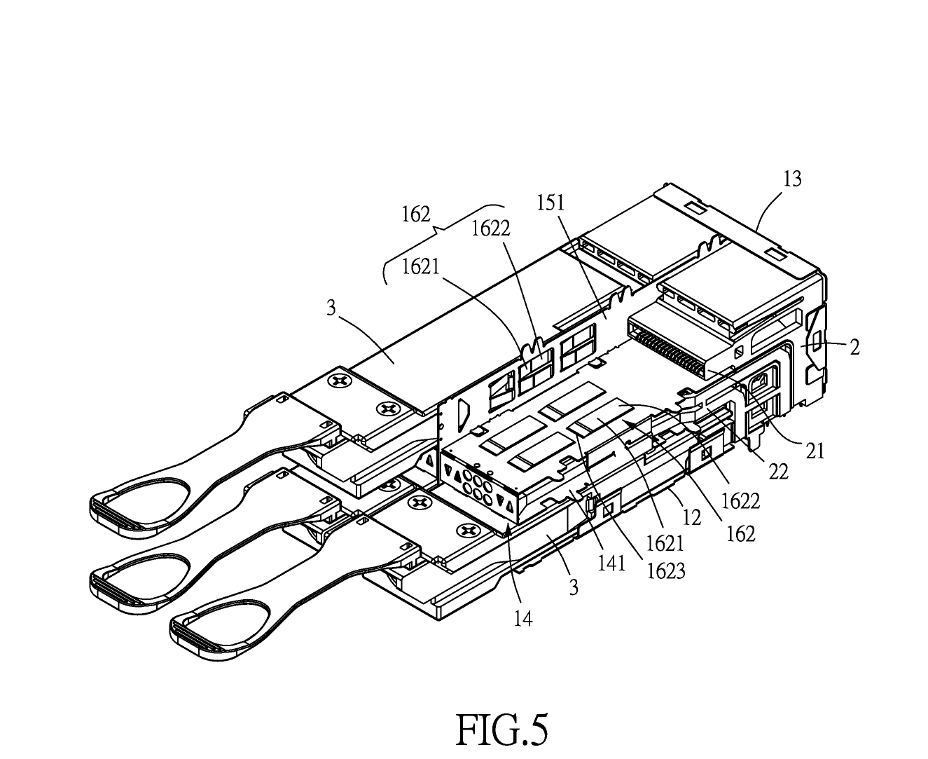

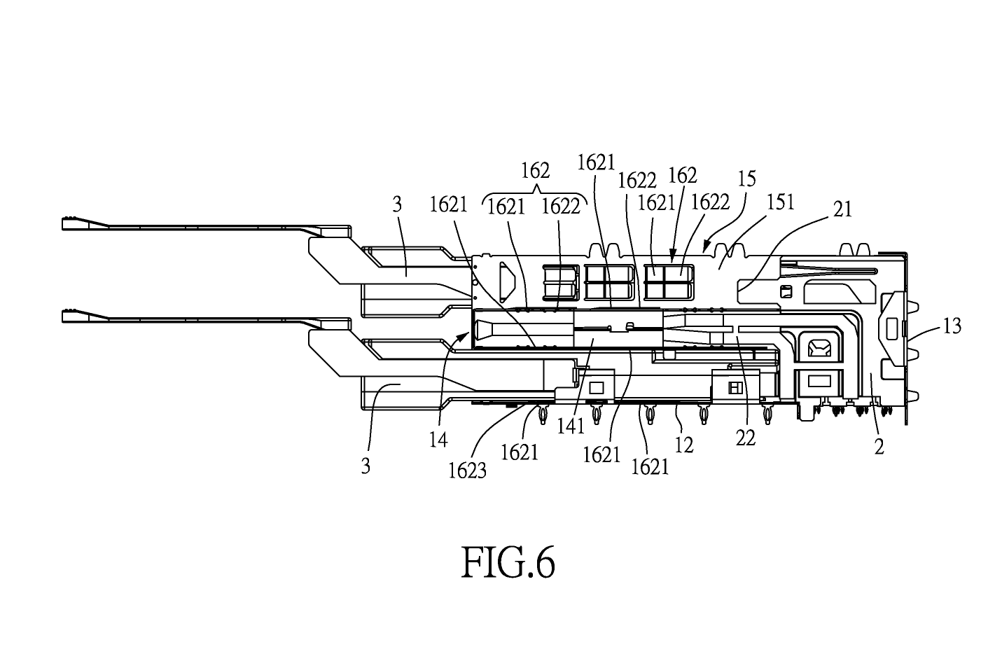

With reference to FIGS. 5 and 6 for the application of a preferred embodiment of the present invention as shown in FIGS. 2 and 3 as well as FIG. 4, when the plug device 3 is plugged into the plug channel 16 of the plug module holder of the present invention through the slot 161 for electrically connecting the electrical connector 21 of the base 2, the thermal conductor 162 is in contact with an external wall of the plug device 3 for directly absorbing and conducting the waste heat produced by the plug device 3 to the casing 1, and then the waste heat on the casing 1 is dissipated to the atmosphere by convection, so as to improve the heat dissipation efficiency and data transmission rate of the plug module holder of the present invention.

With reference to FIGS. 1 to 5 for the plug module holder of the present invention, the thermal conductor 162 is a V-shaped thermal conductive bracket 1621 facing the inside of the plug channel, and a connecting end 1623 of the V-shaped thermal conductive bracket 1621 is coupled to a wall of the plug channel 16, and a free end 1622 of the V-shaped thermal conductive bracket 1621 faces towards the base 2, and the V-shaped thermal conductive bracket 1621 is formed on the wall of the casing 1 by cutting or punching. When the plug device 3 is plugged into the plug channel 16 of the plug module holder of the present invention through the slot 161 for electrically connecting an electrical connector 21 of the base 2, the free end 1622 of the V-shaped thermal conductive bracket 1621 will not hinder the plug device 3. Since the V-shaped thermal conductive bracket 1621 is elastic, therefore a suspending side of the V-shaped thermal conductive bracket 1621 may be pressed onto the external wall of the plug device 3 to contact with the external wall of the plug device 3, so as to directly and quickly absorb and conduct the waste heat produced by the plug device 3 to the casing 1.

In the plug module holder as shown in FIGS. 1 to 6, the casing 1 comprises at least one top-and-bottom spacer 14, and the top-and-bottom spacer 14 is installed in the casing 1 to partition the casing 1 into upper and lower plug channels 16, and the quantity of top-and-bottom spacers 14 may be increased or decreased according to actual requirements. In addition, the thermal conductor 162 may be installed on a top side, a bottom side and both top and bottom sides of the top-and-bottom spacer 14, such that the thermal conductor 162 can be installed on the wall of the plug channel 16 for directly contacting the external wall of the plug device 3.

In the plug module holder as shown in FIGS. 1 to 6, the thermal conductor 162 is a V-shaped thermal conductive bracket 1621 facing the inside of the plug channel 16, and a connecting end 1621 of the V-shaped thermal conductive bracket 1621 is coupled to a top side, a bottom side and both top and bottom sides of the top-and-bottom spacer 14 (coupled to a wall of the plug channel 16) and a free end 1622 of the V-shaped thermal conductive bracket 1621 faces towards the base 2. When the plug device 3 is plugged into the plug channel 16 of the plug module holder of the present invention through the slot 161 for electrically connecting the electrical connector 21 of the base 2, the free end 1622 of the V-shaped thermal conductive bracket 1621 will not hinder the plug device 3. Since the V-shaped thermal conductive bracket 1621 is elastic, therefore a suspending side of the V-shaped thermal conductive bracket 1621 may be pressed onto the external wall of the plug device 3, and contacted with the external wall of the plug device 3 for directly and quickly absorbing and conducting the waste heat produced by the plug device 3 to the casing 1.

In the plug module holder as shown in FIGS. 1 to 6, the top-and-bottom spacer 14 is a U-shaped top-and-bottom partition panel 141 with an opening facing towards the front of the base 2, and the V-shaped thermal conductive bracket 1621 is disposed on a top side, a bottom side and both top and bottom sides of the U-shaped top-and-bottom partition panel 141, and the V-shaped thermal conductive bracket 1621 is formed on a wall on a top side, a bottom side and both top and bottom sides of the U-shaped top-and-bottom partition panel 141 by cutting or punching. Therefore, the U-shaped top-and-bottom partition panel 141 may be installed at the V-shaped thermal conductive bracket 1621 or provided for accommodating a light guide 22 disposed on both sides of the base 2.

In the plug module holder as shown in FIGS. 1 to 6, the casing 1 has at least one left-and-right spacer 15, and the left-and-right spacer 15 is installed in the casing 1 for partitioning the casing 1 into left and right plug channels 16, and the quantity of left-and-right spacer 15 may be increased or decreased according to actual requirements. Therefore, the thermal conductor 162 may be installed on a left side, a right side or both left and right sides of the left-and-right spacer 15, so that the thermal conductor 162 can be installed on a wall of the plug channel 16 for contacting the external wall of the plug device 3 directly.

In the plug module holder as shown in FIGS. 1 to 6, the thermal conductor 162 is a V-shaped thermal conductive bracket 1621 facing the inside of the plug channel 16, and a connecting end of the V-shaped thermal conductive bracket 1621 is coupled to a left side, a right side or both left and right sides of the left-and-right spacer 15 (which is a wall of the plug channel 16), and a free end 1622 of the V-shaped thermal conductive bracket 1621 faces towards the base 2. When the plug device 3 is plugged into the plug channel 16 of the plug module holder of the present invention through the slot 161 for connecting an electrical connector 21 of the base 2, the free end 1622 of the V-shaped thermal conductive bracket 1621 will not hinder the plug device 3. Since the V-shaped thermal conductive bracket 1621 is elastic, therefore the suspending side of the V-shaped thermal conductive bracket 1621 may be pressed onto an external wall of the plug device 3 to contact with the external wall of the plug device 3, so as to directly and quickly absorbing and conducting the waste heat produced by the plug device 3 to the casing 1.

In the plug module holder as shown in FIGS. 1 to 6, the left-and-right spacer 15 is a left-and-right partition panel 151, and the V-shaped thermal conductive bracket 1621 is disposed on a left side, a right side or both left and right sides of the left-and-right partition panel 151, and the V-shaped thermal conductive bracket 1621 is formed on a wall on a left side, a right side or both left and right sides of the left-and-right partition panel 151 by cutting or punching. Therefore, the left-and-right partition panel 151 is capable of absorbing the waste heat produced by the plug device 3 that is installed on the left side and right side of the left-and-right partition panel 151 through the V-shaped thermal conductive bracket 1621 to the casing 1 directly and quickly.

While the invention has been described by means of specific embodiments, numerous modifications and variations could be made thereto by those skilled in the art without departing from the scope and spirit of the invention set forth in the claims.

What is claimed is:

1. A plug module holder, comprising:
a casing, having at least one slot formed at the front of the casing; and
at least one base, disposed at the rear of the casing, and having at least one electrical connector installed at the front of the base, and the casing having at least one plug channel formed therein and disposed between the slot and the electrical connector, and the plug channel having at least one thermal conductor installed on a wall of the plug channel and provided for contacting and plugging a plug device of the plug channel.

2. The plug module holder of claim 1, wherein the thermal conductor includes a V-shaped thermal conductive bracket installed therein and facing towards the plug channel, and a free end of the V-shaped thermal conductive bracket faces towards the base.

3. The plug module holder of claim 1, wherein the casing has at least one top-and-bottom spacer installed in the casing for portioning the casing into upper and lower plug channels.

4. The plug module holder of claim 3, wherein the thermal conductor includes a V-shaped thermal conductive bracket facing towards the inside of the plug channel, and a free end of the V-shaped thermal conductive bracket faces towards the base.

5. The plug module holder of claim 4, wherein the top-and-bottom spacer is a U-shaped top-and-bottom partition panel with an opening facing towards the front of the base, and the V-shaped thermal conductive bracket is situated on a top side, a bottom side or both top and bottom sides of the U-shaped top-and-bottom partition panel.

6. The plug module holder of claim 1, wherein the casing includes at least one left-and-right spacer disposed in the casing for separating left and right plug channels.

7. The plug module holder of claim 6, wherein the thermal conductor includes a V-shaped thermal conductive bracket facing towards the plug channel, and a free end of the V-shaped thermal conductive bracket faces towards the base.

8. The plug module holder of claim 7, wherein the left-and-right spacer is a left-and-right partition panel, the V-shaped thermal conductive bracket is situated on a left side, a right side or both left and right sides.
